(19) United States
(12) Patent Application Publication
(10) Pub. No.: US 2005/0036444 A1
(43) Pub. Date: Feb. 17, 2005

(54) WDM bidirectional add/drop self-healing hubbed ring network

(76) Inventors: Sung-Bum Park, Suwon-si (KR); Seong-Taek Hwang, Pyeongtaek-si (KR)

Correspondence Address: CHA & REITER, LLC, 210 ROUTE 4 EAST STE 103, PARAMUS, NJ, 07652, US

(21) Appl. No.: 10/771,603

(22) Filed: Feb. 4, 2004

(30) Foreign Application Priority Data
Aug. 12, 2003 (KR) 2003-55866

(51) Int. Cl. G01R 31/08

(52) U.S. Cl. 370/222; 370/242

(57) ABSTRACT

A WDM hubbed ring network includes a single central office connected to a plurality of remote nodes by one optical transmission line. The central office generates at each wavelength corresponding to each channel in a first channel group a high-priority optical signal and a low-priority optical signal. These signals are then WDM-multiplexed and transmitted to each of the remote nodes in different directions along the ring via the optical transmission line. The central office receives a high-priority optical signal and a low-priority optical signal with a wavelength corresponding to each channel in a second channel group from the remote nodes via the optical transmission line in different directions.

This application claims priority under 35 U.S.C. § 119 to an application entitled “WDM Bidirectional Add/Drop Self-Healing Hubbed Ring Network,” filed in the Korean Intellectual Property Office on Aug. 12, 2003 and assigned Ser. No. 2003-55866, the contents of which are incorporated herein by reference.

### BACKGROUND OF THE INVENTION

1. Field of the Invention

The present invention relates generally to a wavelength division multiplexing (WDM) optical communication network, and in particular, to a WDM add/drop hubbed ring network.

2. Description of the Related Art

As the required amount of communication traffic used in home is increased due to the spread of the Internet, a metro/access network for connecting a central office (or hub) to subscribers attracts public attention. The metro/access network must be suitable for high-speed data transmission to meet an increasing demand for high-speed service and must also be economical in accommodating many subscribers. A WDM metro/access network can transmit an optical signal using a plurality of wavelengths regardless of its transmission method or data rate, thus efficiently contributing to an increase in data rate and bandwidth of the network. In the metro/access network, a remote node installed near the subscriber-crowded place to connect a central office to subscribers must have a drop function for dropping a desired signal from the central office, e.g. for use by the subscriber, and an add function for transmitting a desired signal to the network.

FIG. 1 is a diagram illustrating a structure of a general hubbed self-healing ring network. As illustrated in FIG. 1, the hubbed self-healing ring network includes a central office (or hub) 10 and remote nodes 20, 30 both connected to the central office 10 via optical fibers 2, 4. Of the two strands of optical fiber, one serves as a working fiber 4 and the other serves as a protection fiber 2. The central office 10 includes a multiplexer (MUX) 11 for multiplexing an optical signal, an erbium-doped fiber amplifier (EDFA) 12 for amplifying the multiplexed optical signal, and a coupler 13 for coupling the amplified optical signal to the optical fibers 2, 4. In addition, the central office 10 includes demultiplexers (DMUX) 14 for demultiplexing optical signals from the optical fibers 2, 4, and optical switches 15 for selecting any one of the optical signals from the optical fibers 2, 4. Each of the remote nodes 20, 30 includes unidirectional add/drop multiplexers (ADM) 41, 42 connected to the optical fibers 2, 4, respectively, and optical switches 43 for selecting any one of the optical signals from the optical fibers 2, 4.

In a normal state of the hubbed self-healing ring network, the central office 10 sends the same optical signals via both of the optical fibers 2, 4. The remote nodes 20, 30 drop all the optical signals received through the optical fibers 2, 4 to the unidirectional add/drop multiplexers 41, 42, and then receive optical signals having a good characteristic from among the dropped optical signals, using the optical switches 43. Likewise, the remote nodes 20, 30 send the same optical signals via the optical fibers 2, 4. The central office 10 then selects one of the two optical signals using the optical switches 15.

FIG. 2 is a diagram illustrating a hubbed self-healing ring network having a system failure. In case of a system failure such as from a cut fiber, the hubbed self-healing ring network performs the following self-healing operation.

As illustrated in FIG. 2, when optical fibers are cut off between a first remote node (RN1) 20 and a second remote node (RN2) 30 in the hubbed self-healing ring network, the second remote node 30 cannot receive a second channel λ2 transmitted counterclockwise via the working fiber 4, so it receives a second channel λ2 transmitted clockwise via the protection fiber 2. In contrast, the first remote node 20 cannot add (or send) a first channel λ1 counterclockwise via the working fiber 4, so it sends the first channel λ1 clockwise via the protection fiber 2 by switching the optical switches 43.

In the conventional hubbed self-healing ring network, the same optical signals are transmitted via optical lines only in a single direction, decreasing efficiency of the optical fibers. In addition, the conventional hubbed self-healing ring network connects a central office to remote nodes with two strands of optical fibers, so each remote node must include separate add/drop multiplexers for adding/dropping optical signals to both of the two optical fibers, increasing the cost undesirably. Moreover, since the central office and the remote nodes must selectively receive any one of the two signals for a self-healing function, the optical switches must be used at every wavelength where optical signals are added and dropped, causing an increase in the cost.

### SUMMARY OF THE INVENTION

It is, therefore, an object of the present invention to provide a WDM bidirectional add/drop self-healing hubbed ring network capable of bidirectionally transmitting an optical signal via one strand of optical fiber between a central office and each remote node, and of securing economical self-healing.

To achieve the above and other objects, there is provided a wavelength division multiplexing (WDM) hubbed ring network in which one central office is connected to a plurality of remote nodes by one optical transmission line. The central office generates a high-priority optical signal and a low-priority optical signal at each wavelength corresponding to a channel in a first channel group. High-priority optical signals and low-priority optical signals of respective channels in the first channel group are WDM-multiplexed. The multiplexed optical signals are transmitted to each of the remote nodes in different directions ring-wise around the ring network by means of the optical transmission line. A high-priority optical signal and a low-priority optical signal are received from the remote nodes at each wavelength corresponding to a channel in a second channel group and in respectively different directions. The remote nodes receive a high-priority optical signal and a low-priority optical signal at a common wavelength that corresponds to a respective channel in the first channel group. The signal is received from the central office by means of the optical transmission line and in respectively different directions. Each remote node generates a high-priority optical signal and a low-priority optical signal at a common wavelength corresponding to a channel in the second channel group. The generated high-priority and low-priority optical signals are transmitted to the central office by means of the optical transmission line and in respectively different directions.

### BRIEF DESCRIPTION OF THE DRAWINGS

The above and other objects, features and advantages of the present invention will become more apparent from the following detailed description when taken in conjunction with the accompanying drawings in which:

FIG. 1 is a diagram illustrating a structure of a general hubbed self-healing ring network;

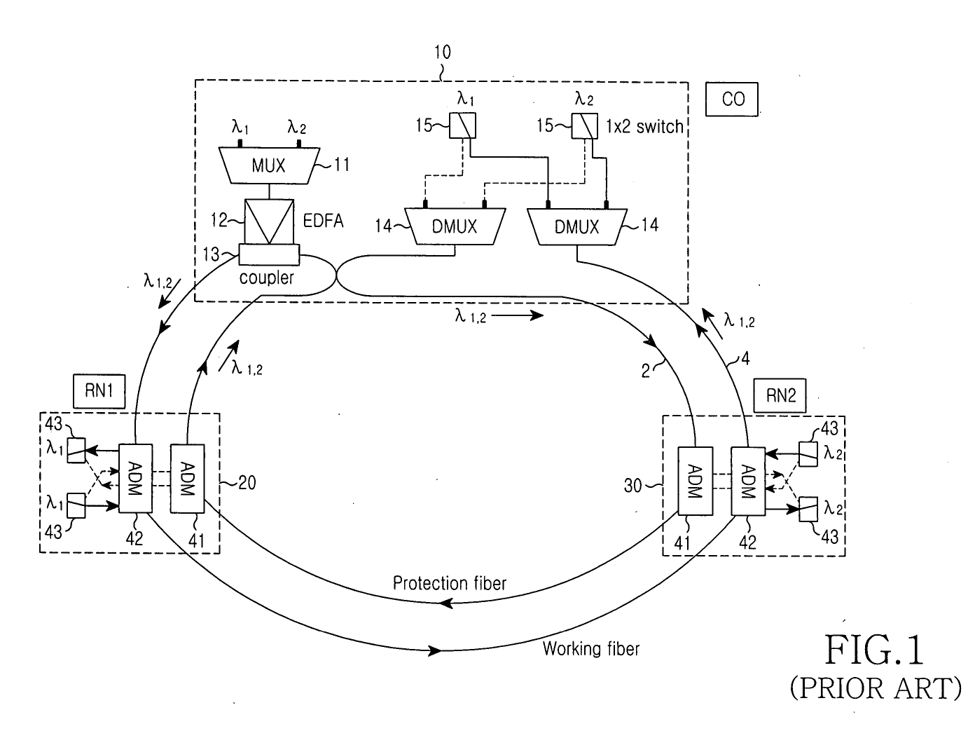

FIG. 2 is a diagram illustrating a hubbed self-healing ring network having a system failure;

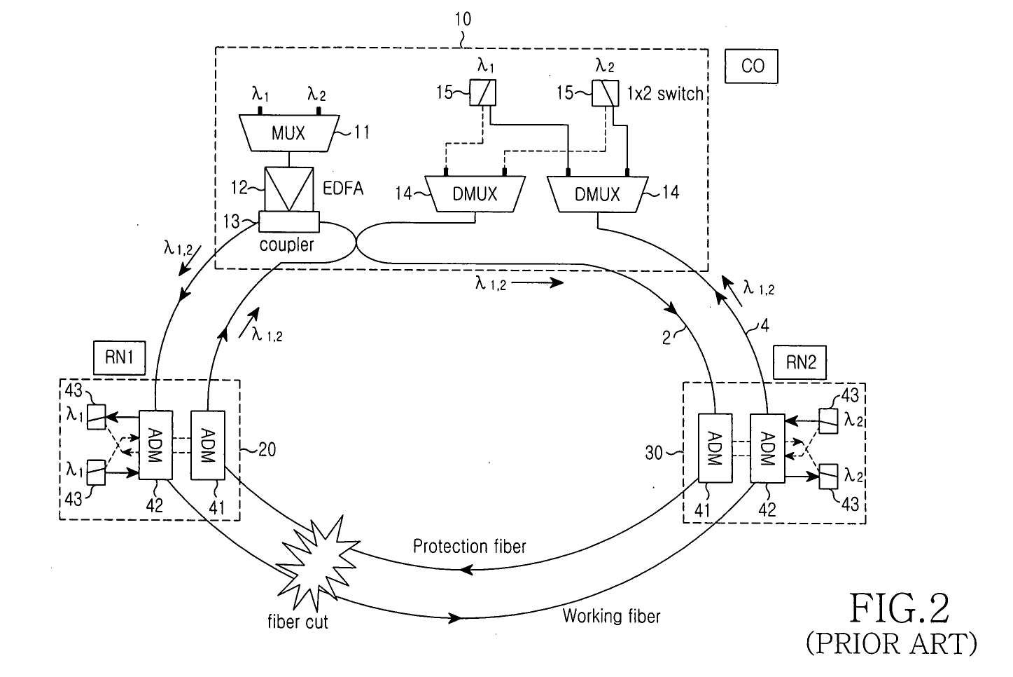

FIG. 3 is a diagram illustrating a structure of a WDM bidirectional add/drop self-healing hubbed ring network according to an embodiment of the present invention;

FIG. 4 is a diagram illustrating a detailed structure of the remote node in the WDM bidirectional add/drop self-healing hubbed ring network of FIG. 3;

FIGS. 5A to 5C are diagrams for explaining an operational principle of the optical switch in the remote node according to an embodiment of the present invention;

FIG. 6 is a diagram for explaining a self-healing procedure of the WDM bidirectional add/drop self-healing hubbed ring network according to an embodiment of the present invention;

FIG. 7 is a diagram for explaining a system monitoring method and an optical switch control method in the central office of the ring network according to an embodiment of the present invention; and

FIG. 8 is a diagram for explaining a system monitoring method and an optical switch control method in the remote node of the ring network according to an embodiment of the present invention.

### DETAILED DESCRIPTION OF THE PREFERRED EMBODIMENT

A preferred embodiment of the present invention will now be described in detail with reference to the annexed drawings. Detailed description of known functions and configurations incorporated herein has been omitted for conciseness.

A self-healing hubbed ring network according to the present invention can bidirectionally transmit an optical signal via one add/drop multiplexer at each remote node. Since each add/drop multiplexer is bidirectional, only a single optical transmission line is needed throughout the network. This doubles transmission capacity compared with a unidirectional system. For each remote node, two bidirectionally-added, i.e. added to signaling in both directions ring-wise around the network, optical signals are identical in wavelength although of different priority. Likewise, two bidirectionally-dropped optical signals are also identical in wavelength although of different priority. In other words, optical signals bidirectionally received at any given add/drop multiplexer are identical in wavelength and optical signals bidirectionally transmitted from any given add/drop multiplexer are also identical in wavelength. This makes it possible to realize the network using low-priced optical elements. When such a bidirectional add/drop multiplexer is used, if a system failure occurs, each remote node can preferentially recover an optical signal having higher priority using one 2×2 optical switch. Therefore, the proposed hubbed ring network can increase the efficiency of optical fiber utilization, realize a remote node with low-priced optical elements, and efficiently heal the network by itself using a small number of optical switches.

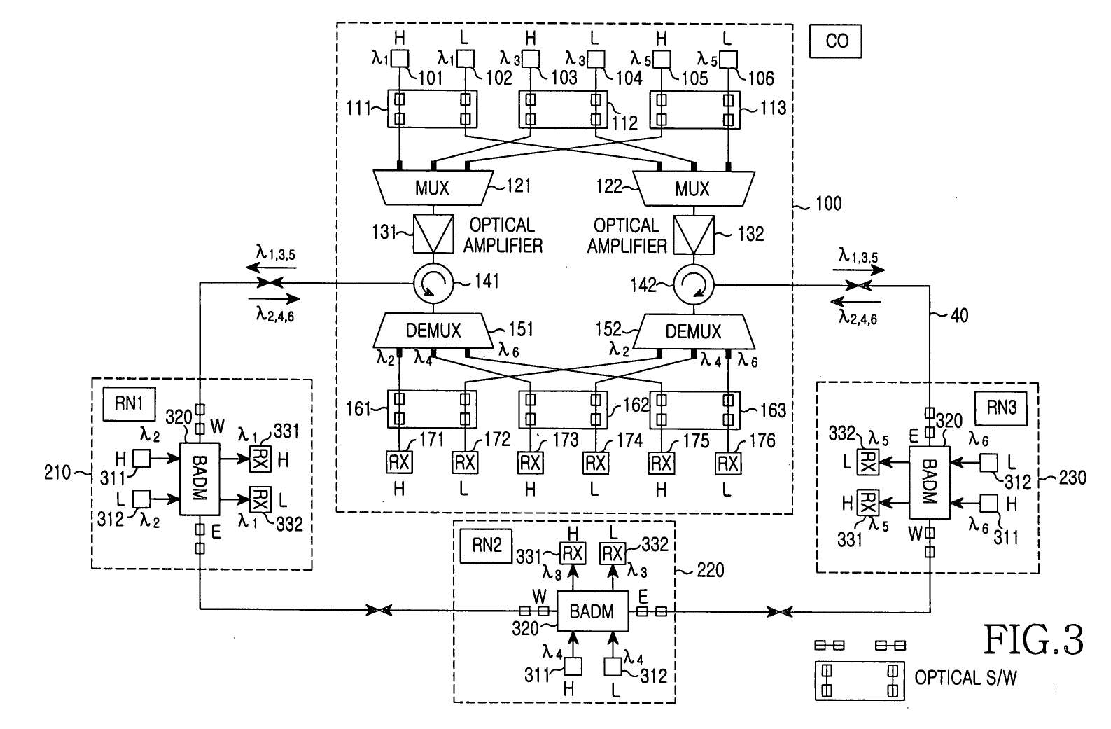

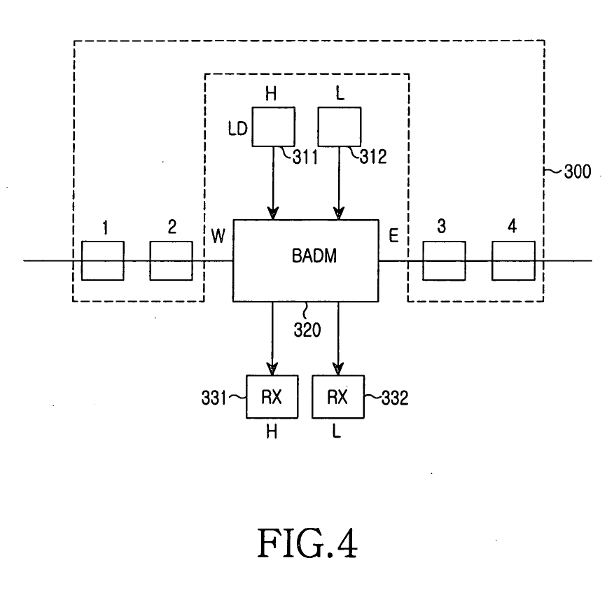

FIG. 3 is a diagram illustrating a structure of a WDM bidirectional add/drop self-healing hubbed ring network according to an embodiment of the present invention, and FIG. 4 is a diagram illustrating in detail the structure of the remote node in the WDM bidirectional add/drop self-healing hubbed ring network of FIG. 3.

The WDM bidirectional add/drop self-healing hubbed ring network according to the invention bifurcates by priority the information to be conveyed on each transmission/reception channel. That is, on each channel, there is generated an optical signal having higher priority and an optical signal having lower priority. In the invention, transmission/reception of an optical signal having higher priority (or high-priority optical signal) is given preference to transmission/reception of an optical signal having lower priority (or low-priority optical signal).

In addition, it is noted that, in either the central office or any remote node, an optical signal added is different in wavelength from an optical signal dropped.

Referring to FIG. 3, the WDM bidirectional add/drop self-healing hubbed ring network according to the present invention includes one central office 100 and a plurality of remote nodes 210, 220, 230. FIG. 3 shows three remote nodes, by way of example. The central office 100 includes light sources 101, 103, 105 for generating optical signals having higher priority for each channel and light sources 102, 104, 106 for generating optical signals having lower priority for each channel. Also included are optical switches 111, 112, 113 for switching optical signals to be bidirectionally transmitted via an optical transmission line 40 to first and second multiplexers (MUX) 121, 122 according to their priority. The first and second multiplexers 121, 122 multiplex the optical signals with higher priority and the optical signals with lower priority. In the normal state, and as will be described in more detail below, the multiplexer 121 multiplexes only high priority signals and the other multiplexer 122 multiplexes only low priority signals, as shown in FIG. 3. Optical amplifiers 131, 132 amplify the multiplexed optical signals from the first and second multiplexers 121, 122, respectively. Preferably, an erbium-doped fiber amplifier (EDFA) is used for the optical amplifiers 131, 132. In addition, the central office 100 includes first and second demultiplexers (DMUX) 151, 152 for demultiplexing the optical signals having higher priority and the optical signals having lower priority, transmitted bidirectionally via the optical transmission line 40. Further included are optical switches 161, 162, 163 for switching the optical signals transmitted bidirectionally from the optical transmission line 40 to receivers (RX) 171 to 176 according to their priority, and the receivers 171 to 176 for receiving the demultiplexed optical signals having higher priority and the demultiplexed optical signals having lower priority according to channels. Moreover, the central office 100 includes circulators 141, 142 for outputting to the optical transmission line 40 optical signals received from the optical amplifiers 131, 132 connected to the optical transmission line 40, and outputting optical signals received from the optical transmission line 40 to the first and second demultiplexers 151, 152.

Referring to FIGS. 3 and 4, each of the remote nodes 210, 220, 230 includes light sources 311, 312 for generating an optical signal having higher priority and an optical signal having lower priority, respectively, in terms of a wavelength of a transmission channel. Each remote node 210, 220, 230 also includes a bidirectional add/drop multiplexer (BADM) 320 for dropping the optical signal having higher priority and the optical signal having lower priority at a wavelength of a reception channel transmitted from the optical transmission line 40, and adding the optical signal having higher priority and the optical signal having lower priority, outputted from the light sources 311, 312. Also included are receivers (RX) 331, 332 for receiving the optical signal having higher priority and the optical signal having lower priority, respectively, at a wavelength of the reception channel from the bidirectional add/drop multiplexer 320. In addition, each of the remote nodes 210, 220, 230 includes an optical switch 300 installed between the bidirectional add/drop multiplexer 320 and the optical transmission line 40, to perform a switching operation so that in case of a system failure, an optical signal having higher priority can be recovered first.

The central office 100 WDM-multiplexes odd channels and transmits the WDM-multiplexed channels in both directions of the optical transmission line 40. Specifically, as described above, the central office 100 gives priority to an optical signal of each channel, generates an optical signal having higher priority and an optical signal having lower priority for one wavelength, or one channel, and transmits the generated optical signals in both directions of the optical transmission line 40. That is, optical signals traveling from the central office 100 to both sides of the optical transmission line 40 are identical in wavelength, but modulated with different information. Thus, the signaling transmitted on one side is high priority and, on the other side, low priority. Such optical signals transmitted in both directions of the optical transmission line 40 are dropped at the respective remote nodes 210, 220, 230. For example, a first remote node (RN1) 210 drops only a first channel λ1 which is an odd channel, among optical signals received from both sides. In the same manner, a second remote node (RN2) 220 and a third remote node (RN3) 230 drop only a third channel λ3 and a fifth channel λ5, respectively, both of which are odd channels. Each of the remote nodes 210, 220, 230, in a manner similar to that of the central office 100, gives priority to one wavelength corresponding to each transmission channel. Each remote node 210, 220, 230 adds an even channel having higher priority, and an even channel having lower priority and modulated with different information, and bidirectionally transmits the added channels up to the central office 100. The first, second and third remote nodes 210, 220, 230 add second, fourth and sixth channels λ2, λ4, λ6, respectively, all of which are even channels, and then bidirectionally transmit the added channels.

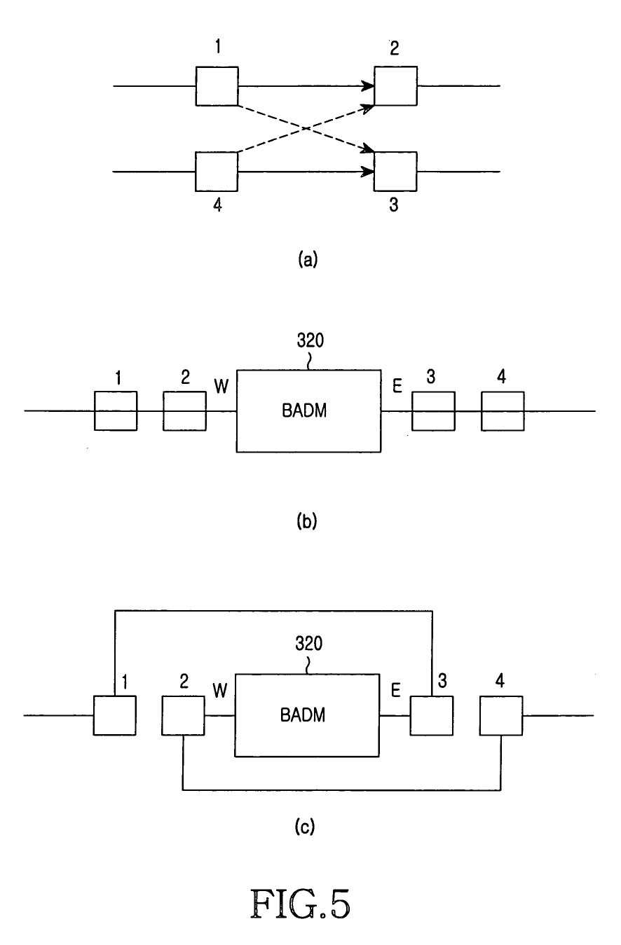

FIGS. 5A to 5C are diagrams for explaining an operational principle of the optical switch in the remote node according to an embodiment of the present invention. As illustrated in FIG. 5A, in a normal state, the optical switch 300 is connected in parallel, so that a first port is connected to a second port, and a third port is connected to a fourth port. However, in a protection state, the optical switch 300 is crossed, so that the first port is connected to the third port, and the second port is connected to the fourth port. In effect, the connections to the second and third ports are swapped with respect to source ports on the connections. FIG. 5B illustrates the connection between the bidirectional add/drop multiplexer 320 and the optical switch 300 in a normal state. In this case, the second port and the third port of the optical switch 300 are connected to a W (West) port and an E (East) port of the bidirectional add/drop multiplexer 320, respectively, and the first port and the fourth port are connected to the optical transmission line 40. FIG. 5C shows the connection between the bidirectional add/drop multiplexer 320 and the optical switch 300 in a protection state. In this case, the optical switch 300 is crossed, so that the E port and the W port of the bidirectional add/drop multiplexer 320 are connected to the left optical transmission line and the right optical transmission line, respectively.

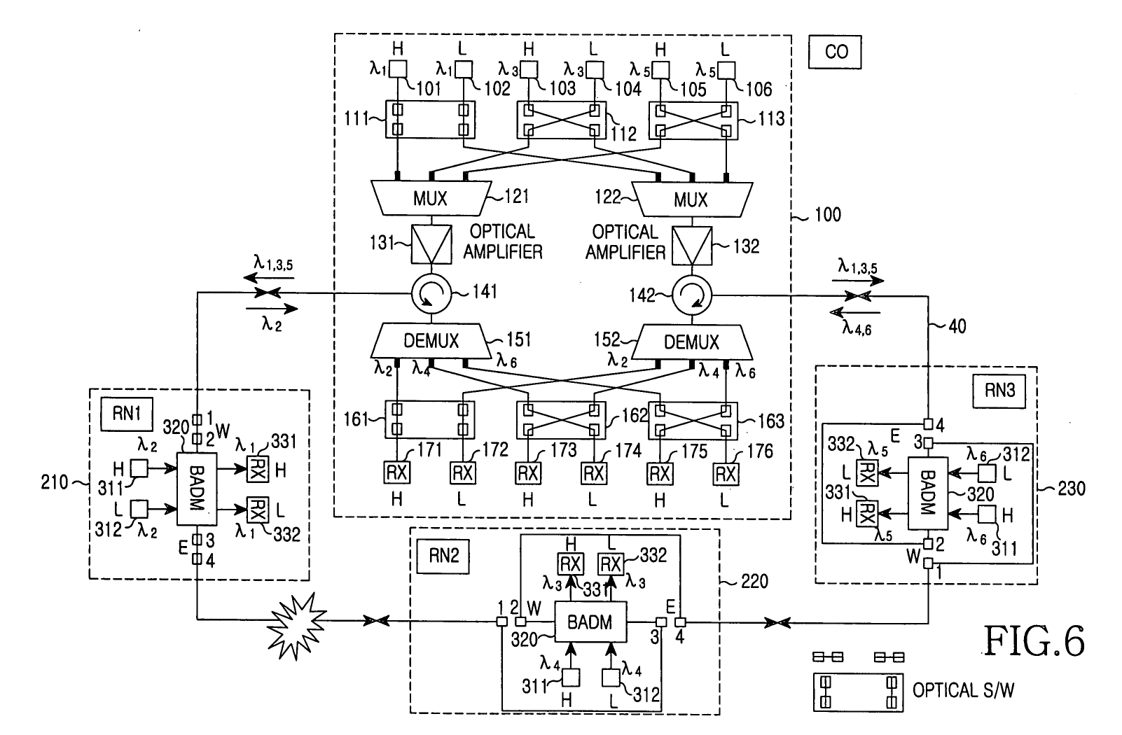

FIG. 6 is a diagram for explaining a self-healing procedure of the WDM bidirectional add/drop self-healing hubbed ring network according to an embodiment of the present invention. As illustrated in FIG. 6, in the central office 100, an optical signal sent counterclockwise from the first multiplexer 121 to the remote nodes 210, 220, 230 is higher in priority than an optical signal sent clockwise from the second multiplexer 122 to the remote nodes 210, 220, 230. Similarly, in each of the remote nodes 210, 220, 230, an optical signal having higher priority is generated from the high-priority light source 311 and transmitted clockwise up to the central office 100 via the bidirectional add/drop multiplexer 320, while an optical signal having lower priority is generated from the low-priority light source 312 and transmitted counterclockwise via the bidirectional add/drop multiplexer 320. That is, in the central office 100 and the remote nodes 210, 220, 230, transmission/reception terminals denoted by H are higher in priority than transmission/reception terminals denoted by L.

In case of a system failure, the ring network can determine whether a system failure has occurred, and if it has occurred, determine a system-failed position, by monitoring power of optical signals received at reception terminals of the central office 100 and the remote nodes 210, 220, 230. For example, if a system failure occurs due to the cutoff of the optical transmission line 40 between the first remote node 210 and the second remote node 220, the ring network according to the present. invention changes switching states of the optical switches in the central office 100 and the remote nodes 210, 220, 230 according to a position of the failure in order to first protect the optical signal having higher priority.

As illustrated in FIG. 6, in the normal state the first remote node 210 can receive a high-priority optical signal with a first wavelength λ1 from the central office 100 counterclockwise, and transmit a high-priority optical signal with a second wavelength λ2 clockwise. However, the second and third remote nodes 220, 230 cannot receive high-priority optical signals on the optical transmission line 40 counterclockwise. Accordingly, the central office 100 changes switching states of the optical switches 112, 113 connected to the light sources 103, 105 for generating high-priority optical signals with a wavelength to be received, to a cross-switched state, and sends high-priority optical signals with a third wavelength λ3 and a fifth wavelength λ5 on the optical transmission line 40 clockwise. In addition, the 2×2 optical switch 300 connected to both ends of the bidirectional add/drop multiplexer 320 in each of the second and third remote nodes 220, 230 is switched as illustrated in FIG 5C, so that a high-priority optical signal sent from the central office 100 is applied to the W port of the bidirectional add/drop multiplexer 320 and then provided to the high-priority receiver 331. A nalogously, the second and third remote nodes 220, 230 can transmit high-priority optical signals with a fourth wavelength λ4 and a sixth wavelength λ6 generated from their light sources 311 up to the central office 100 counterclockwise. The central office 100 also switches switching states of the optical switches 162, 163 to a cross-switched state, so that high-priority optical signals with a fourth wavelength λ4 and a sixth wavelength λ6 transmitted from the second and third remote nodes 220, 230 are received at the high-priority receivers 173, 175. Therefore, in the hubbed ring network according to the present invention, when an optical fiber is cut, transmission capacity is halved from that in the normal state, but an optical signal with higher priority can be preferentially protected.

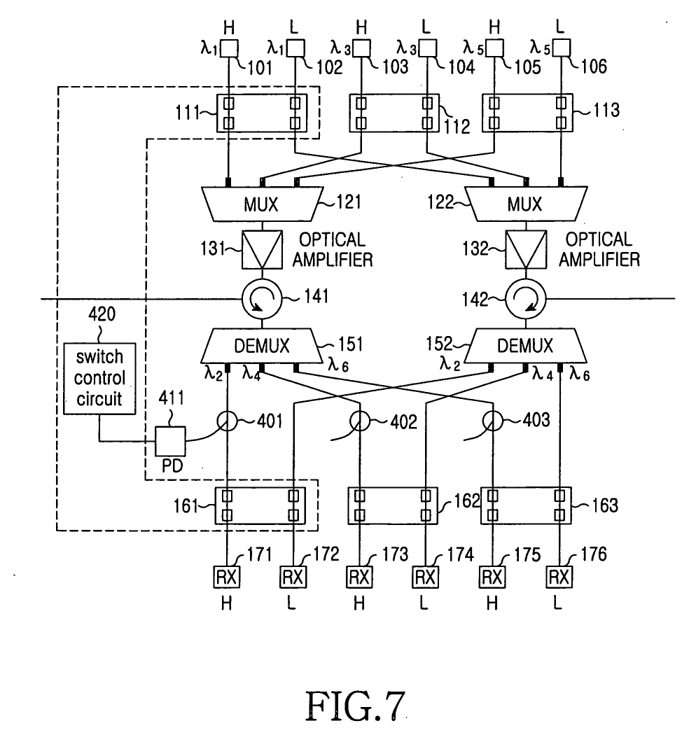

FIG. 7 is a diagram for explaining a system monitoring method and an optical switch control method in the central office of the ring network according to an embodiment of the present invention. Referring to FIG. 7, optical signals multiplexed with the same wavelength, received bidirectionally from the central office 100 via the optical transmission line 40, are demultiplexed by the WDM demultiplexers 151, 152. 10:90 optical couplers 401, 402, 403 are connected to reception ports, from each of which a high-priority optical signal is output out of the two demultiplexed signals having the same wavelengths. A photo-diode is connected to each of the optical couplers 401, 402, 403 to detect power of an optical signal output from a 10/100 terminal of the corresponding optical coupler and simultaneously control a pair of optical switches located in a transmission terminal and a reception terminal according to presence/absence of the optical signal. Although a photo diode (PD) 411 is shown to be connected only to the optical coupler 401 in FIG. 7, separates photo diodes (not shown) are individually connected even to the other optical couplers 402, 403. The photo diodes are connected to their associated optical switch control circuits (not shown). If it is assumed that a particular remote node receives a first wavelength λ1 and transmits a second wavelength λ2, the first and second wavelengths λ1 and λ2 make a pair, and in transmission and reception terminals of the central office 100, two optical switches 111, 161 associated with the first and second wavelengths λ1 and λ2 are controlled by one optical switch control circuit 420. In an embodiment represented by FIG. 7, two optical switches 112, 162 associated with third and fourth wavelengths λ3 and λ4 and two optical switches 113, 163 associated with a fifth wavelength λ5 and a sixth wavelength λ6 are controlled by their optical switch control circuits (not shown).

Specifically, in FIG. 7, since an optical signal received from the left of the optical transmission line 40 has higher priority, the optical couplers 401, 402, 403 for detecting optical signals with unique wavelengths are connected to output terminals of the demultiplexer 151. For example, a high-priority optical signal with a second wavelength λ2 is applied to the photo diode 411 via the optical coupler 401. The photo diode 411 provides the detected optical power to the optical switch control circuit 420, so that the optical switch control circuit 420 controls the optical switches 111, 161. When a high-priority optical signal with a second wavelength λ2 is received from an output terminal of the demultiplexer 151, the optical switches 111, 161 hold a normal state, i.e., a parallel-switched state. However, if the high-priority optical signal with a second wavelength λ2 is not received from the output terminal of the demultiplexer 151 due to a system failure, the optical switch control circuit 420 simultaneously changes switching states of the optical switches 111, 161 in the transmission terminal and the reception terminal to a cross-switched state. In the case of the fourth wavelength λ4 and the sixth wavelength λ6 also, optical switches are controlled in the same method as the second wavelength. In this manner, the central office 100 can monitor presence/absence of a system failure and, in case of a system failure, monitor a position of the failure.

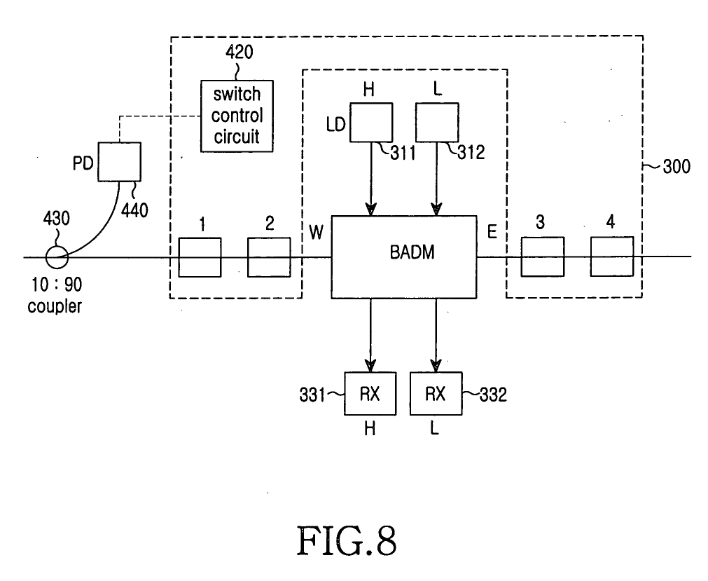

FIG. 8 is a diagram for explaining a system monitoring method and an optical switch control method in the remote node of the ring network according to an embodiment of the present invention. If it is assumed that an optical signal received via a W port in the bidirectional add/drop multiplexer 320 included in each of the remote nodes 210, 220, 230 has higher priority, it is possible to determine presence/absence of a system failure by monitoring power of an optical signal with higher priority. As illustrated in FIG. 8, in each of the remote nodes 210, 220, 230, a 10:90 optical coupler 430 is connected to a front end of the 2×2 optical switch 300 on the optical transmission line 40, where a high-priority optical signal is received in a normal state. A photo diode 440 is connected to the optical coupler 430, and an optical switch control circuit 420 is connected to the photo diode 440. The photo diode 440 detects optical power at a 10/100 terminal of the optical coupler 430, and provides its result to the optical switch control circuit 420. The optical switch control circuit 420 controls a switching state of the optical switch 300 according to the detection result on the optical power from the photo diode 440.

If optical reception power is higher than or equal to a predetermined level in the normal state, the optical switch 300 holds a parallel-switched state. However, if a high-priority optical signal is not received due to occurrence of a system failure, the optical switch 300 changes its switching state to a cross-switched state, so the high-priority optical receiver 331 drops an optical signal received from the right of the optical transmission line 40 in FIG. 8. Likewise, a high-priority optical signal that was added (transmitted) to the left of the optical transmission line 40 in the normal state travels to the right of the optical transmission line 40 in FIG. 8 as its path is changed by the optical switch 300.

As can be understood from the foregoing description, the WDM bidirectional add/drop self-healing hubbed ring network according to the present invention can increase efficiency of an optical fiber by using only one strand of optical fiber, and double transmission capacity by bidirectionally transmitting optical signals with the same wavelength modulated with different information, from the central office to the remote nodes. In addition, a bidirectional add/drop multiplexer constituting each remote node can be economically realized. Moreover, in case of a system failure, it is possible to simply determine presence/absence of the failure by monitoring optical power, and effectively protect a high-priority optical signal by providing only one optical switch to each remote node.

While the invention has been shown and described with reference to a certain preferred embodiment thereof, it will be understood by those skilled in the art that various changes in form and details may be made therein without departing from the spirit and scope of the invention as defined by the appended claims.

1. A wavelength division multiplexing (WDM) hubbed ring network in which one central office is connected to a plurality of remote nodes by one optical transmission line, said network comprising:
said one central office, said one central office being configured for generating a high-priority optical signal and a low-priority optical signal at each wavelength corresponding to a channel in a first channel group, WDM-multiplexing high-priority optical signals and low-priority optical signals of respective channels in the first channel group, transmitting the multiplexed optical signals to each of the remote nodes in different directions ring-wise a round said ring network by means of said one optical transmission line, and receiving from said remote nodes, at each wavelength corresponding to a channel in a second channel group and in respectively different directions ring-wise around said ring network, a high-priority optical signal and a low-priority optical signal; and
said remote nodes, said remote nodes being configured for receiving from said central office by means of said one optical transmission line and in respectively different directions ring-wise around said ring network a high-priority optical signal and a low-priority optical signal at a common wavelength that corresponds to a respective channel in the first channel group, generating a high-priority optical signal and a low-priority optical signal at a common wavelength corresponding to any channel in the second channel group, and transmitting to the central office by means of said one optical transmission line and in respectively different directions ring-wise around said ring network the generated high-priority and low-priority optical signals at said common wavelength corresponding to said any channel in the second channel group.

2. The WDM hubbed ring network of claim 1, wherein said central office comprises:
a plurality of light sources for generating a high-priority optical signal and a low-priority optical signal for each channel in the first channel group;
multiplexers for WDM-multiplexing the high-priority optical signal and the low-priority optical signal of each channel in the first channel group;
demultiplexers for demultiplexing a high-priority optical signal and a low-priority optical signal of each channel in the second channel group, transmitted bidirectionally from the optical transmission line; and
a plurality of receivers for receiving the demultiplexed high-priority optical signal and low-priority optical signal for each channel.

3. The WDM hubbed ring network of claim 2, wherein said central office further comprises:
first optical switches for setting a path to the multiplexers, according to priorities, for the high-priority optical signal and the low-priority optical signal of each channel in the first channel group from the light sources; and
second optical switches for setting a path to the receivers according to priorities, for the high-priority optical signal and the low-priority optical signal of each channel in the second channel group, transmitted bidirectionally from the optical transmission line.

4. The WDM hubbed ring network of claim 3, wherein said central office monitors presence/absence of a system failure by measuring for each channel the output created by the demultiplexer in the demultiplexing of said high-priority optical signal.

5. The WDM hubbed ring network of claim 4, wherein said central office comprises:
optical couplers each connected to an output terminal of each channel's optical signal from the demultiplexer for demultiplexing the high-priority optical signal in the second channel group, the optical coupler extracting a high-priority optical signal;
photo diodes connected to the associated optical couplers, for detecting optical power of each channel's optical signal; and
optical switch control circuits connected to the associated photo diodes, for simultaneously controlling the optical switches according to optical powers detected by the photo diodes.

6. The WDM hubbed ring network of claim 3, wherein the first optical switches are individually selectively actuatable to heal the network in response to topologically where on the ring network a break in the optical transmission line has occurred.

7. The WDM hubbed ring network of claim 6, wherein the healing preferentially provides for the first channel group a transmission path along the optical transmission line to a high-priority signal over its respective low-priority signal at said common wavelength.

8. The WDM hubbed ring network of claim 7, wherein the second optical switches are individually selectively actuatable to heal the network in response to topologically where on the ring network a break in the optical transmission line has occurred.

9. The WDM hubbed ring network of claim 8, wherein the healing preferentially provides for the second channel group a transmission path along the optical transmission line to a high-priority signal over its respective low-priority signal at said common wavelength.

10. The WDM hubbed ring network of claim 3, wherein the second optical switches are individually selectively actuatable to heal the network in response to topologically where on the ring network a break in the optical transmission line has occurred.

11. The WDM hubbed ring network of claim 10, wherein the healing preferentially provides for the second channel group a transmission path along the optical transmission line to a high-priority signal over its respective low-priority signal at said common wavelength.

12. The WDM hubbed ring network of claim 2, wherein the central office further comprises a circulator connected to the optical transmission line, for outputting the multiplexed optical signals in the first channel group from the multiplexers to the optical transmission line, and outputting the optical signals in the second channel group, received from the optical transmission line, to the demultiplexers.

13. The WDM hubbed ring network of claim 1, wherein each of the remote nodes comprises:
light sources for generating, for a given channel in the second channel group, an optical signal having higher priority and an optical signal having lower priority;
a bidirectional add/drop multiplexer for dropping a high-priority optical signal and a low-priority optical signal of a given channel in the first channel group, transmitted from the optical transmission line, and adding to said optical transmission line the optical signals generated for said given channel in the second channel group; and
receivers for receiving the dropped optical signals.

14. The WDM hubbed ring network of claim 13, wherein each of the remote nodes further comprises an optical switch installed between the bidirectional add/drop multiplexer and said optical transmission line, for performing a switching operation so that in case of a system failure, the optical signal having higher priority can be recovered first.

15. The WDM hubbed ring network of claim 14, wherein each of the remote nodes monitors presence/absence of a system failure by measuring a high-priority optical signal of a channel in the first channel group, said optical signal of a channel in the first channel group having been transmitted from the optical transmission line for said measuring.

16. The WDM hubbed ring network of claim 15, wherein each of the remote nodes comprises:
optical couplers each connected to the optical transmission line where a high-priority optical signal is received in a normal state, for extracting a high-priority optical signal;
a photo diode for detecting an optical power of a high-priority optical signal extracted by an optical coupler of said optical couplers; and
an optical switch control circuit connected to the photo diode, for controlling the optical switch of the respective remote node according the detected optical power.

17. The WDM hubbed ring network of claim 14, wherein the optical switch in each remote node comprises a 2×2 optical switch having two pairs of ports, each pair being, in said ring network, ring-wise on opposite sides of the bidirectional add/drop multiplexer, wherein the ports of one of the two pairs are connected in parallel to the ports of the other of the two pairs in a normal state, whereas the connections to the other of the two pairs of ports are reconfigured to swap respective sources from among said one of the two pairs in response to a system failure.

18. A central office of a wavelength division multiplexing (WDM) hubbed ring network in which one central office is connected to a plurality of remote nodes by one optical transmission line, said central office being configured for generating a high-priority optical signal and a low-priority optical signal at each wavelength corresponding to a channel in a first channel group, WDM-multiplexing high-priority optical signals and low-priority optical signals of respective channels in the first channel group, transmitting the multiplexed optical signals to each of the remote nodes in different directions ring-wise a round said ring network by means of said one optical transmission line, and receiving from said remote nodes, at each wavelength corresponding to a channel in a second channel group and in respectively different directions ring-wise around said ring network, a high-priority optical signal and a low-priority optical signal.

19. A WDM hubbed ring network comprising the central office of claim 18, said network further comprising said remote nodes, said remote nodes being configured for receiving from said central office by means of said one optical transmission line and in respectively different directions ring-wise around said ring network a high-priority optical signal and a low-priority optical signal at a common wavelength that corresponds to a respective channel in the first channel group.

20. The WDM hubbed ring network of claim 19, said remote nodes being further configured for generating a high-priority optical signal and a low-priority optical signal at a common wavelength corresponding to any channel in the second channel group, and transmitting to the central office by means of said one optical transmission line and in respectively different directions ring-wise around said ring network the generated high-priority and low-priority optical signals at said common wavelength corresponding to said any channel in the second channel group.
